(19) United States
(12) Patent Application Publication
(10) Pub. No.: US 2021/0035698 A1
(43) Pub. Date: Feb. 4, 2021

(54) SYSTEM AND METHOD FOR APPLIANCE MONITORING

(71) Applicant: Vectorform, LLC, Royal Oak, MI (US)

(72) Inventors: Woody Floyd, Seattle, WA (US); Jeffrey Meador, Birmingham, MI (US); Steven Zaske, Seattle, WA (US); Jason Richard Crispell, Apopka, FL (US); Joseph S. Wisniewski, Livonia, MI (US)

(21) Appl. No.: 16/943,074

(22) Filed: Jul. 30, 2020

Related U.S. Application Data
(60) Provisional application No. 62/880,907, filed on Jul. 31, 2019.
(60) Provisional application No. 62/915,782, filed on Oct. 16, 2019.

(51) Int. Cl. G16Y 40/35; G16Y 40/40; G16Y 40/20; G16Y 20/30; G16Y 20/20

(52) U.S. Cl. CPC G16Y 40/35; G16Y 40/40; G16Y 10/80; G16Y 20/30; G16Y 20/20; G16Y 40/20

(57) ABSTRACT

A system for monitoring a device includes, among other things, at least one sensor adjacent a device, and a controller coupled to the at least one sensor. The controller includes a comparison module operable to determine that at least one predetermined criterion is met in response to comparing one or more values sensed by the least one sensor, the at least one predetermined criterion based on a total number of cycles associated with operation of the device. A method of monitoring a device is also disclosed.

### CROSS-REFERENCE TO RELATED APPLICATIONS

This application claims priority to U.S. Provisional Application No. 62/880,907, filed on Jul. 31, 2019; and U.S. Provisional Application No. 62/915,782, filed on Oct. 16, 2019.

### BACKGROUND

This disclosure relates to monitoring of devices, such as an appliance associated with a consumable item.

Appliances such as dishwashers, clothes dryers and coffee makers may utilize a consumable item during operation. A quantity of the consumable item may be stocked for later consumption during operation of the appliance.

### SUMMARY

A system for monitoring a device according to an exemplary aspect of the present disclosure includes, among other things, at least one sensor adjacent a device, and a controller coupled to the at least one sensor. The controller includes a comparison module operable to determine that at least one predetermined criterion is met in response to comparing one or more values sensed by the least one sensor, the at least one predetermined criterion based on a total number of cycles associated with operation of the device.

In a further non-limiting embodiment of the foregoing system, the comparison module is operable to generate an alert in response to determining that a predetermined cycle threshold is met, and the predetermined cycle threshold is based on a consumable item associated with the device.

In a further non-limiting embodiment of the foregoing system, the at least one sensor is fixedly attached to an external surface of the device.

In a further non-limiting embodiment of the foregoing system, the at least one sensor is an accelerometer.

In a further non-limiting embodiment of the foregoing system, the at least one sensor is a gyroscope.

A method of monitoring a device according to an exemplary aspect of the present disclosure includes, among other things, sensing one or more conditions of a device, determining a total number of cycles associated with the device in response to comparing the sensed conditions to an operating profile established for the device, setting a cycle counter based on the total number of cycles, and generating an alert in response to determining that the cycle counter is equal to or less than a predetermined cycle threshold.

In a further non-limiting embodiment of the foregoing method, the one or more conditions relate to vibration of the device.

A system for monitoring a device according to an exemplary aspect of the present disclosure includes, among other things, at least one sensor adjacent a device, and a controller coupled to the at least one sensor. The controller includes a comparison module operable to determine that at least one predetermined criterion is met in response to comparing one or more values sensed by the least one sensor. The at least one predetermined criterion is based on a total number of cycles associated with operation of the device.

In a further non-limiting embodiment of the foregoing system, the comparison module is operable to generate an alert in response to determining that a predetermined cycle threshold is met, and the predetermined cycle threshold is based on a quantity of a consumable item associated with the device.

In a further non-limiting embodiment of the foregoing system, the device is associated with one or more operating profiles, and the comparison module is operable to determine that the at least one predetermined criterion is met in response to comparing one or more values sensed by the least one sensor to the one or more operating profiles, and the at least one predetermined criterion includes one or more predetermined operating thresholds associated with the one or more operating profiles.

In a further non-limiting embodiment of the foregoing system, the device is a washing machine, a clothes dryer or a coffee maker.

In a further non-limiting embodiment of the foregoing system, the at least one sensor is an accelerometer or a gyroscope fixedly attached to an external surface of the device.

In a further non-limiting embodiment of the foregoing system, the comparison module is operable to generate an alert in response to determining an occurrence of a maintenance event associated with at least one predetermined maintenance threshold.

In a further non-limiting embodiment of the foregoing system, the comparison module is operable to determine movement of a door assembly of the device between open and closed positions in response to the at least one predetermined criterion being met.

In a further non-limiting embodiment of the foregoing system, the device is a washing machine, and the comparison module is operable to generate an alert in response to determining a non-occurrence of moving the door assembly between the open and closed positions subsequent to completion of a wash cycle.

In a further non-limiting embodiment of the foregoing system, the comparison module is operable to generate an alert in response to determining a failure to initiate a cycle associated with operation of the device.

In a further non-limiting embodiment of the foregoing system, the at least one sensor is an accelerometer.

In a further non-limiting embodiment of the foregoing system, the at least one sensor is a gyroscope.

A system for monitoring a device according to an exemplary aspect of the present disclosure includes, among other things, an appliance associated with a consumable item and one or more operating profiles, and at least one sensor secured to the appliance. The at least one sensor is operable to sense one or more conditions of the appliance in operation. A controller includes a processor and a memory, and an interface module coupled to the at least one sensor. A comparison module is operable to determine that at least one predetermined criterion is met in response to comparing one or more values of the one or more conditions sensed by the least one sensor to the one or more operating profiles. The at least one predetermined criterion is based on a total number of cycles associated with operation of the device.

In a further non-limiting embodiment of the foregoing system, the device is a washing machine or a clothes dryer, and the one or more operating profiles include expected values of the one or more conditions.

In a further non-limiting embodiment of the foregoing system, the comparison module is operable to generate an alert in response to determining that the total number of cycles exceeds a predetermined cycle threshold, and the predetermined cycle threshold is associated with a quantity of the consumable item.

In a further non-limiting embodiment of the foregoing system, the alert corresponds to a reorder request of the consumable item.

In a further non-limiting embodiment of the foregoing system, the comparison module is operable to reset a cycle counter associated with the total number of cycles in response to a delivery notification communicated to the controller, and the delivery notification corresponds to fulfillment of the reorder request.

In a further non-limiting embodiment of the foregoing system, the one or more operating profiles relate to vibration of the appliance in operation, and the at least one sensor is an accelerometer or a gyroscope operable to sense vibration of the appliance in operation.

In a further non-limiting embodiment of the foregoing system, the at least one sensor is fixedly attached to an external surface of the device, and the controller and the sensor are at least partially received in a common housing.

A method of monitoring a device according to an exemplary aspect of the present disclosure includes, among other things, establishing one or more operating profiles for an appliance, sensing one or more conditions of the appliance, determining a total number of cycles associated with the appliance in response to comparing the sensed conditions to the one or more operating profiles, setting a cycle counter based on the total number of cycles, and generating an alert in response to determining that a present value of the cycle counter is equal to or less than a predetermined cycle threshold.

In a further non-limiting embodiment of the foregoing method, the one or more conditions include vibration of the appliance.

In a further non-limiting embodiment of the foregoing method, the sensing step includes sensing vibration of the appliance with an accelerometer or a gyroscope secured to the appliance.

In a further non-limiting embodiment of the foregoing method, the appliance is associated with a consumable item, and further includes setting the predetermined cycle threshold based on a quantity of the consumable item prior to the determining step. The alert is a reorder request relating to the quantity of the consumable item.

The various features and advantages of this disclosure will become apparent to those skilled in the art from the following detailed description. The drawings that accompany the detailed description can be briefly described as follows.

### BRIEF DESCRIPTION OF THE DRAWINGS

The various features and advantages of the disclosed examples will become apparent to those skilled in the art from the following detailed description. The drawings that accompany the detailed description can be briefly described as follows.

FIG. 1 illustrates an exemplary monitoring system.

FIG. 2 illustrates a perspective view of an exemplary controller and sensor.

FIG. 3 illustrates circuitry of the controller and sensor of FIG. 2.

FIG. 4 illustrates an exemplary monitoring package that can be utilized with the system of FIG. 1.

FIG. 5 illustrates an exemplary operating profile.

FIG. 6 illustrates another exemplary operating profile.

FIG. 7 illustrates an exemplary process for monitoring a device.

### DETAILED DESCRIPTION

Disclosed is a system and method for monitoring an appliance or other device. An alert or notification can be generated in response to determining that one or more predetermined criterion are met, such as a maintenance alert or reorder request for a consumable item associated with operation of the device.

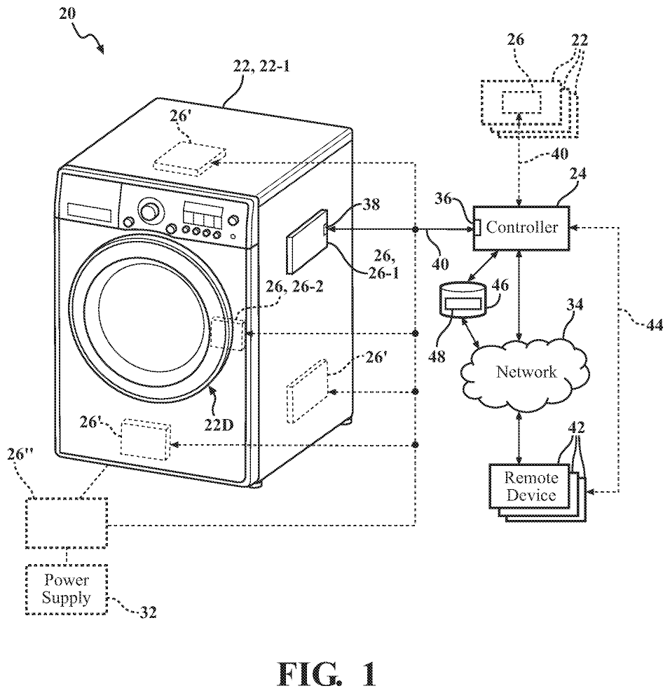

FIG. 1 illustrates an example system 20 for monitoring one or more devices 22 such as a household or commercial appliance. In the illustrative example of FIG. 1, device 22-1 is a washing machine. Other example devices 22 include coffee makers, garbage disposals, clothes dryers, sump pumps and HVAC devices such as furnaces and air conditioners. Other devices and systems may benefit from the teachings disclosed herein, including devices that generate mechanical and/or thermal signals during operation.

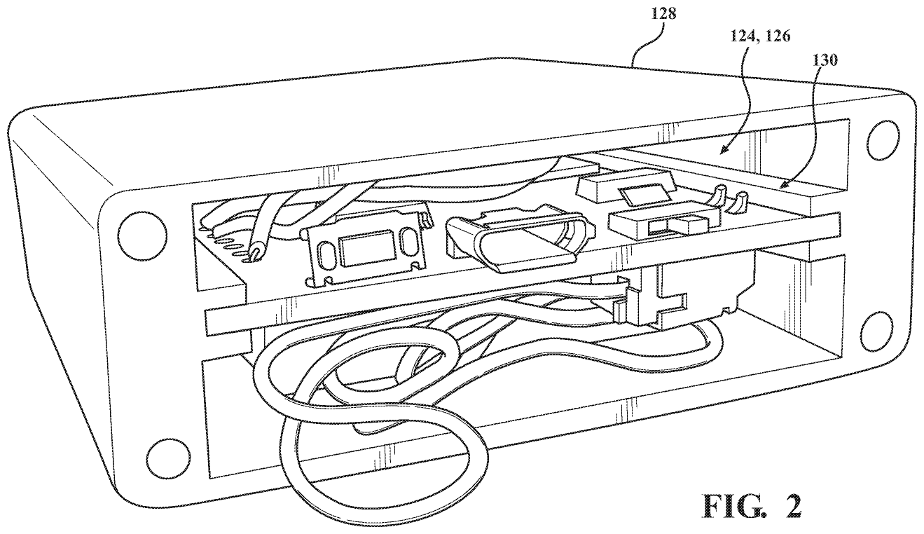

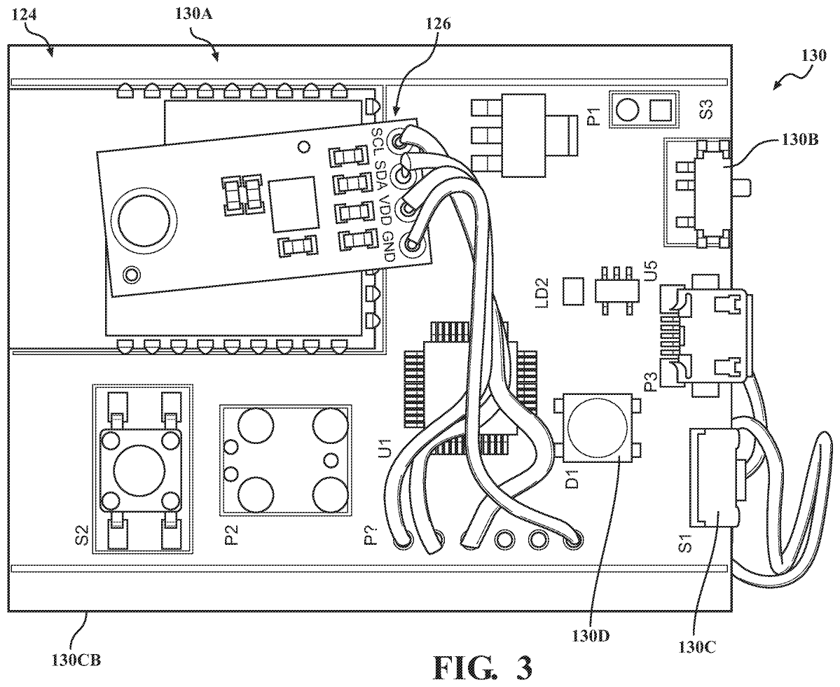

The system 20 includes a controller 24 coupled to one or more sensors 26. Each sensor 26 is operable to measure one or more conditions of a respective device 22. Each sensor 26 can be positioned internal or external to the device 22. In the illustrative example of FIG. 1, sensor 26-1 is fixedly attached or otherwise secured to an external surface of the device 22. One or more sensors 26 can be situated at various positions relative to the device 22, as illustrated by sensors 26′ (shown in dashed lines for illustrative purposes). In examples, at least one of the sensors 26/26′ is operable to determine a position of an access point or door assembly 22D of the device 22 (e.g., open and closed positions). In examples, the system 20 includes a separate or dedicated sensor 26 (indicated at 26-2 in dashed lines for illustrative purposes) coupled to or otherwise placed in close proximity to the door assembly 22D to determine the position of the door assembly 22D. Sensor 26-2 can be any of the sensor configurations disclosed herein. Other sensor configurations can be utilized for the sensor 26-2, such as a magnetic latch coupled to the door assembly 22D. Various techniques can be utilized to secure each sensor 26, such as adhesive, Velcro or one or more fasteners. In examples, the sensor 26 is placed in close proximity to the device 22 at a sufficient distance to measure one or more conditions of the device 22. In the illustrative example of FIG. 1, the controller 24 and sensor(s) 26 are separate and distinct components. In the illustrative example of FIGS. 2-3, the controller and sensor are integrated or combined into a single unit.

Various sensors 26 can be utilized to measure one or more conditions of the respective device 22, such as one or more mechanical and/or thermal signals.

The controller 24 and sensors 26 can be configured to execute one or more software programs. In examples, the controller 24 is more than one computer jointly configured to process software instructions serially or in parallel. In other examples, the controller 24 and/or sensor(s) 26 are analog devices configured with the functionality disclosed herein.

The controller 24 and sensors 26 can include a computer processor, memory, storage means, network device and input and/or output devices and/or interfaces according to some examples. The memory may, for example, include UVPROM, EEPROM, FLASH, RAM, ROM, DVD, CD, a hard drive, or other computer readable medium which may store data and/or the monitoring software disclosed herein. In some examples, the controller 24 and sensors 26 include an input device, such as a keyboard and mouse, and one or more output devices such as a monitor, speakers, printers, etc. The controller 24 and each sensor 26 can be a desktop computer, a laptop computer, a mobile device such as a smart phone or a tablet, a single board computer, or any other computer device.

The controller 24 includes a communications interface 36 that is operable to communicate with a communications interface 38 of each respective sensor 26. The interfaces 36, 38 cooperate to establish a communications link or path 40. The communications path 40 can be a hardwire (e.g., Ethernet) or wireless connection utilizing a various communications protocols, such as WiFi, Bluetooth such as Bluetooth Low Energy (BLE), ZigBee, and 2G/3G/4G/5G cellular protocols. One would understand how to configure the controller 24 and sensor(s) 26 to communicate in view of the teachings disclosed herein.

In examples, the controller 24 and/or sensors 26 are configured to communicate with one or more networks such as a network 34 comprised of one or more computing devices. The network 34 may be a private local area network (LAN), a private wide area network (WAN), the Internet, a mesh network, a cloud computing network, or any other network as is known in the art.

The controller 24 is operable to perform one or more communications functions including sending and/or receiving email, text and other data and information with one or more remote devices 42, such as a host computer or server.

The controller 24 and remote devices 42 include a network interface. The interface facilitates communication with the other systems and/or components of the network utilizing various communications protocols such as Transmission Control Protocol/Internet Protocol (TCP/IP), User Datagram Protocol (UDP), hyper-text transfer protocol (HTTP), simple mail transfer protocol (SMTP), file transfer protocol (FTP), Message Queuing Telemetry Transport (MQTT), and the like. In examples, the controller 24 is operable to communicate with the remote devices 42 directly via a direct interface 44 or over the network 34.

The system 20 can include one or more storage systems 46, which in some examples is operable to store data and other information communicated by the controller 24 and/or sensors 26. In examples, the storage system 46 is a storage area network device (SAN) configured to communicate with the controller 24 and/or remote device(s) 42 directly or over the network 34. In other examples, the storage system 46 is incorporated within the controller 24 or within at least one of the sensors 26. The storage system 46 may be configured to store one or more of computer software instructions, data, emails, text messages, images or other media files, database files, and configuration information, for example. In alternative examples, the controller 24 and/or the one or more sensors 26 are configured to communicate data and other information in a cloud computing environment or to one or more third-party data locations via one or more web services. Each storage system 46 can provide at least one database 48 for storing data and other information.

FIGS. 2-3 illustrate an exemplary controller 124 and sensor 126 that can be incorporated into the system 20. In this disclosure, like reference numerals designate like elements where appropriate and reference numerals with the addition of one-hundred or multiples thereof designate modified elements that are understood to incorporate the same features and benefits of the corresponding original elements.

The controller 124 and sensor 126 are at least partially received in a common enclosure or housing 128. The controller 124 includes circuitry 130. Example circuitry 130 includes a HUZZAH32-ESP32-WROOM-32 (with WiFi+BLE) Feather Board manufactured by Adafruit® Industries, LLC. Referring to FIG. 3, the circuitry 130 includes a circuit board 130CB, a processor 130A and memory for storing and executing one or more software instructions, a power switch 130B, a button 130C along a perimeter of the circuit board for user input, an indicator 130D such as a light emitting diode (LED) for user feedback, a communications interface (e.g., WiFi and BLE). The circuitry 130 can include connectors for an onboard power source such as a battery or can include an interface for being be powered by an external power source. The circuit board 130CB has a generally rectangular geometry. However, it should be appreciated that other geometries for the circuit board 130CB can be utilized, such as a generally elliptical or circular geometry. The sensor 126 includes an accelerometer operable to measure, detect or sense vibrations of the respective device 22 (FIG. 1) during operation. An example accelerometer includes an ADXL343+ADT7410 Sensor FeatherWing manufactured by Adafruit Industries, LLC integrated with a temperature sensor for obtaining temperature information. Although the disclosure primarily refers to sensors 26, 126 being an accelerometer, other sensors 26, 126 can be utilized including gyroscopes operable to measure, detect or sense vibrations of the respective device. In the illustrative example of FIGS. 2-3, the controller 124 and sensor 126 are integrated together in one housing 128 on a single circuit board 130CB. In other examples, the controller 124 and sensor 126 are coupled to separate circuit boards and/or received in separate housings. It should be appreciated that the components of the circuitry 130 are exemplary, and the circuitry 130 can have fewer or more components to execute the functionality disclosed herein. The sensor 126 can be programmed with software and/or firmware to provide the logic for measuring or sensing condition(s) of the device 22. In another example, sensor 26″ (FIG. 1) is operable to measure or sense a present value of one or more electrical parameters between the device 22 and a power supply 32, such as current drawn by the device 22.

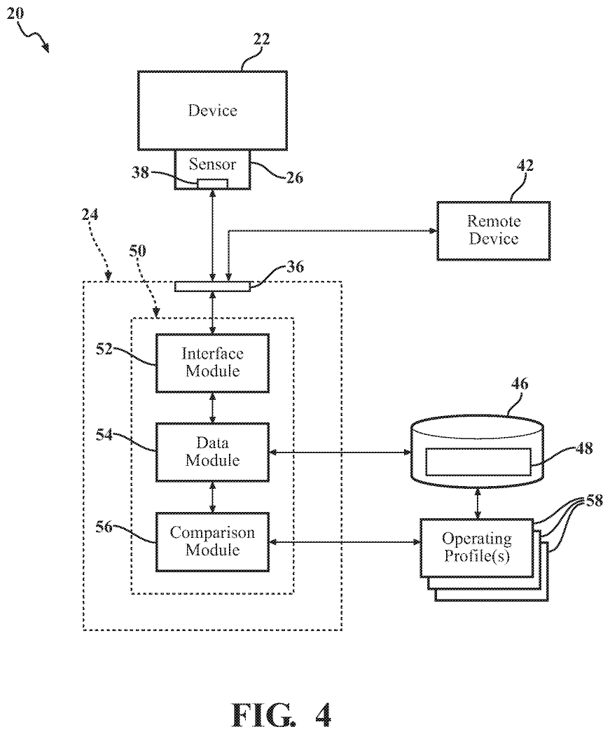

Referring to FIG. 4, with continuing reference to FIG. 1, the system 20 includes a monitoring package 50 for monitoring one or more conditions of the device(s) 22. The controller 24 can be configured to execute the monitoring package 50. The monitoring package 50 includes an interface module 52, data module 54 and comparison module 56 coupled to each other. The interface module 52 is operable to send and/or receive data and other information between the controller 24 and sensor(s) 26 via the communications interface 36 utilizing any of the techniques disclosed herein.

The data module 54 is operable to interface with local and/or external memory, such as the storage system 46, and/or database 48, including storing and retrieving data and other information associated with operation of the device 22.

The comparison module 56 is operable to determine a total number of complete cycles and sub-cycles of the device 22 based on one or more conditions measured or sensed by the sensor(s) 26 associated with each respective device 22. Various techniques for determining the total number of complete cycles and/or sub-cycles of the device 22 can be utilized, such as determining a magnitude and/or change in acceleration or vibration frequencies, and machine learning based on previously sensed values by the sensor(s) 26. In examples, the comparison module 56 is operable to determine a position of the door assembly 22D (FIG. 1) based on one or more conditions measured or sensed by the sensor(s) 26 associated with each respective device 22. The comparison module 56 can be operable to execute one or more signal analysis techniques and/or machine learning to evaluate a stream of sensed values or data from each sensor 26, including accelerometer data.

One or more operating profiles 58 can be established for each respective device 22. Each operating profile 58 can include expected values of the one or more conditions to be measured by each sensor 26, such as duration, frequency and/or amplitude of each parameter associated with a particular condition. Each operating profile 58 can be expressed as a formulaic relationship or curve, or as a value or range of values, for example. Each operating profile 58 can include selectable settings of the device 22, such as a selected duration of the respective cycle or sub-cycle. For example, device 22 can be a washing machine having a set of predefined cycles (e.g., normal, delicate and heavy) selectable by an operator, and a subset of predefined sub-cycles (e.g., presoak, wash, spin, rinse, and final spin), which can be associated with a set of load sizes (e.g., small, medium and large) selectable by the operator. In examples, an operating profile 58 is established with respect to each position of the door assembly 22D (FIG. 1). Each operating profile 58 can be established based on previously observed values and/or parametric relationships, for example.

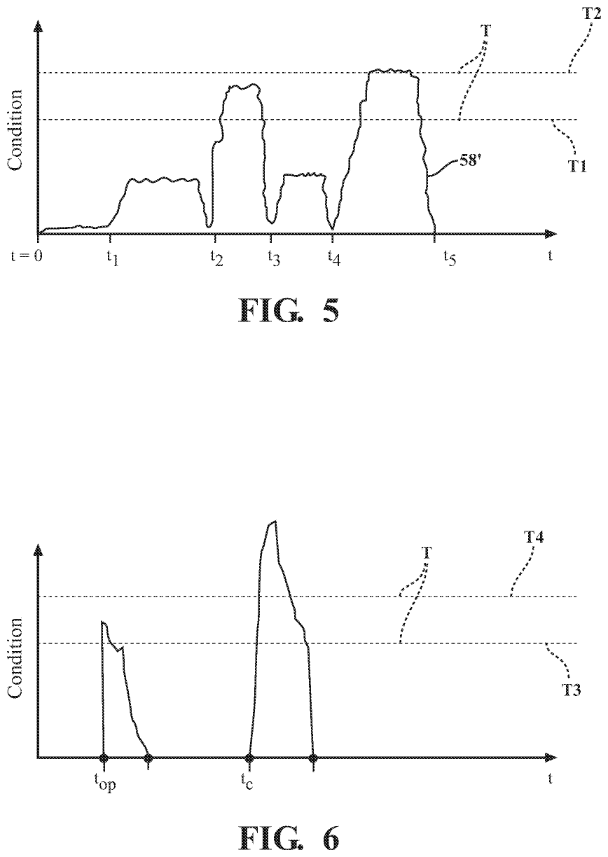

FIG. 5 illustrates an example operating profile 58′ corresponding to a single instance of a cycle of the device 22, such as a washing cycle. The operating profile 58′ may correspond to vibrations expected or observed during a cycle of the device 22. Time t=t₀ can correspond to initiation of a washing cycle, such as a prewash sub-cycle. Times t=t₁, t=t₂, t=t₃, and t=t₄, can correspond to the occurrence of discrete sub-cycles, such as wash, spin, rinse and final spin sub-cycles. Time t=t₅ can correspond to completion of the cycle. One or more predetermined thresholds T (e.g., T1, T2) can be established for the respective operating profile 58′. Each predetermined operating threshold can be established for a respective sub-cycle of the device 22.

FIG. 6 illustrates an example operating profile 58″ corresponding to moving the door assembly 22D between an open position and a closed position, such as prior to, during and/or after a cycle of the device 22 including after the completion of a wash cycle. The operating profile 58″ may correspond to vibrations or forces expected or observed during moving the door assembly 22D between the open and closed positions. Time t=t_{OP} can correspond to moving the door assembly 22D from the closed position to the open position, and time t=t_{C} can correspond to moving the door assembly 22D from the open (or partially open) position to the closed position. Time t=t_{OP} and/or time t=t_{C} can occur subsequent to time t=t₅ (FIG. 5), for example. One or more predetermined thresholds T (e.g., T3, T4) can be established for the respective operating profile 58″. Each predetermined operating threshold T3, T4 can be established for a respective open and closed position of the door assembly 22D.

The comparison module 56 is operable to determine the occurrence of an on and/or off operating state and/or each sub-cycle and cycle of the device 22 in response to comparing the condition(s) measured or sensed by each sensor 26 to the respective operating profile(s) 58 or predetermined operating thresholds T. In examples, the comparison module 56 determines the occurrence of each sub-cycle and/or cycle in response to determining that value(s) of the sensed condition(s) (e.g., magnitude) are equal to and/or exceed the predetermined threshold(s) T. The comparison module 56 can be operable to determine the completion of a cycle, and can be operable to forecast or infer when a cycle is expected to be completed subsequent to determining that a cycle has been initiated.

In examples, the comparison module 56 is operable to determine the occurrence of moving the door assembly 22D between the open and closed positions in response to comparing the condition(s) measured or sensed by each sensor 26 to the respective operating profile 58″ or predetermined operating thresholds T (e.g., T3, T4). Meeting one or more predetermined criterion for determining that the occurrence of moving the door assembly 22D between the open and closed positions can be based on the occurrence of one or more other thresholds T. In examples, the comparison module 56 is operable to determine the occurrence of moving the door assembly 22D between the open and closed positions based on the thresholds T1 and/or T2 being previously met during the cycle of the device 22 and the thresholds T3 and/or T4 also being met. The occurrence of threshold T4 can correspond to a forceful shut of the door assembly 22D, for example.

The comparison module 56 can be operable to apply sampling or filtering of the data or information communicated from each sensor 26. For example, the comparison module 56 may compare an average of the sensed values to the predetermined threshold(s) T to determine whether the predetermined criterion is met. In another example, the comparison module 56 determines that the respective predetermined criterion is met in response to determining that the sensed values are equal to and/or exceed the predetermined threshold(s) T for a predetermined duration (e.g., 1-5 minutes). In examples, the comparison module 56 is operable to ignore accelerometer readings and other sensed values associated with handling or moving the device 22 and other potential sources of false readings. In other examples, the comparison module 56 is operable to ignore periods of non-activity when the device 22 is between sub-cycles and/or other steps of the cycle (e.g., between filling water and spinning).

In examples, predetermined inventory or cycle threshold(s) are established to indicate a low supply or need for replenishment of a consumable item associated with operation of the device 22, such as dishwasher pods or dryer sheets. In other examples, predetermined maintenance threshold(s) are established to indicate an occurrence of an incomplete cycle or maintenance event. The maintenance event may relate to an instantaneous and/or long-term abnormal operating mode or mechanical condition of the device 22, such as a worn component (e.g., bearing) or imbalance condition. The comparison module 56 is operable to generate a notification of the maintenance event for servicing by a user or maintenance personnel. The comparison module 56 is operable to perform long term tracking of malfunctions to provide useful feedback to the user and/or a third party such as device manufacturer regarding preventative maintenance or appliance replacement suggestions.

The comparison module 56 is operable to determine a total number of sub-cycles and/or complete cycles that have occurred. The comparison module 56 is operable to store an inventory or cycle counter in memory, and is operable to decrement (or increment) the cycle counter in response to determining that a cycle and/or sub-cycle of the device 22 has been completed. The comparison module 56 is operable to compare a present value of the cycle counter to the predetermined cycle threshold(s). The predetermined cycle threshold(s) may be set based on a total quantity of consumable item(s) associated with operation of the device 22, such as a value of 20 or 30 items available to the device 22.

The comparison module 56 is operable to generate an alert in response to determining that the predetermined cycle threshold(s) is met. In examples, the alert is an audible and/or visual signal communicated by the controller 24 and/or sensor 26. Example alerts include completion of a cycle, and failure to initiate and/or complete a cycle. For example, the comparison module 56 can be operable to generate a reminder alert indicating that the device 22 was not previously run. In another example, the alert is a notification communicated to the remote device 42, such as a client application and/or an Amazon® Alexa device. The notification may correspond to a reorder request of the consumable item(s) associated with the device 22. The comparison module 56 is operable to reset the cycle counter in response to a delivery or supply notification communicated to the controller 24. The delivery or supply notification can correspond to fulfillment of the reorder request by a third party vendor such as Amazon®. The comparison module 56 is operable to manage inventory of consumables items used for laundry, such as dryer sheets and laundry pods. Other example consumable items can include single serving coffee cartridges or pods. A user can interact with a client application executed on a mobile device operated by a user, for example, to select consumable items from the third party vendor to automatically reorder the consumable items (e.g., through Amazon® Dash Replenishment Services).

The package 50 can include a client application for facilitating interaction between a user and the system 20. The client application can include features for account creation, log in, pairing a controller 24 and/or sensor 26 to a home network and account, sensor 26 naming, LED color for user feedback, third party vendor account interaction, selection of consumable items for automatic and/or manual reordering, input of a quantity or inventory of consumable items on hand, managing other inventory and reorder settings, and viewing reorder statuses. Other features of the client application can include setting an expected operating schedule of the device 22, including a number of loads of laundry per week, which can be utilized to set the predetermined inventory or cycle threshold. Still other features of the client application can include setting up notifications for end of cycle and/or malfunctions of the device 22.

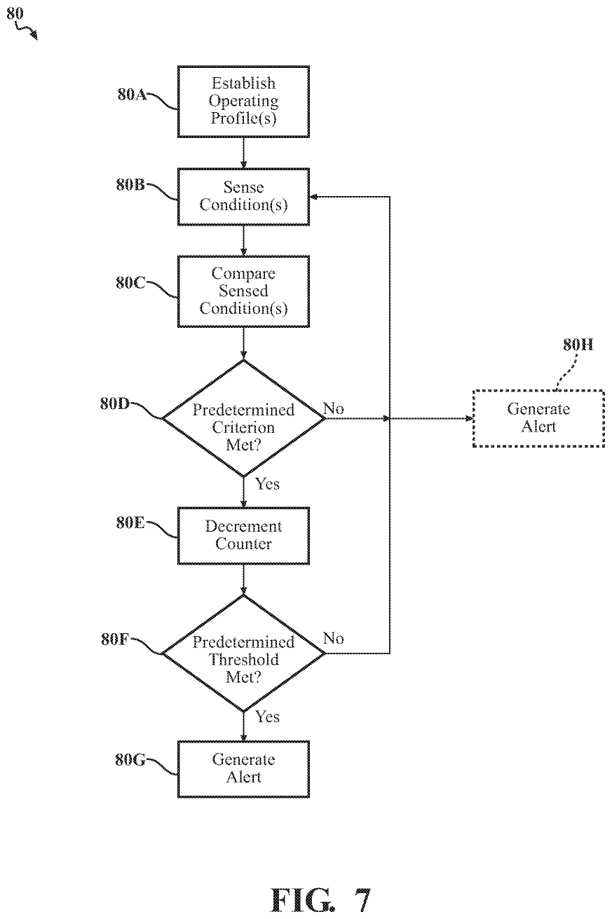

FIG. 7 illustrates an example process in a flowchart 80 monitoring an appliance or other device. The process 80 can be utilized with the system 20 of FIG. 1 and can be executed by one or more portions of the package 50 of FIG. 4, such as the comparison module 56. The controller 24 can be programmed with logic or otherwise configured to execute the process 80. Reference is made to FIG. 4 for illustrative purposes.

At step 80A, one or more operating profiles 58 can be established for the respective device 22. Step 80A can include establishing one or more predetermined operating thresholds T (FIG. 5 and/or FIG. 6) for each operating profile 58.

At step 80B, one or more conditions of the device 22 are measured or sensed by the sensor(s) 26 secured or otherwise adjacent to the device 22. At step 80C, value(s) of the sensed condition(s) are compared to the operating profiles 58 and/or predetermined operating thresholds T. At step 80D, the controller 24 determines whether one or more predetermined criterion are met, including any of the predetermined criterion disclosed herein. For example, the controller 24 can determine whether the predetermined criterion is met in response to the sensed value(s) being equal to or exceeding the predetermined operating threshold(s) T.

At step 80E, an inventory or cycle counter can be decremented (or incremented) in response to the predetermined criterion being met. The predetermined cycle counter can be previously set to an initial quantity of the consumable item that is available for consumption by the device 22. When a cycle or sub-cycle is complete, the package 50 will deduct a predefined quantity from the cycle counter to indicate consumption of one or more of the consumable items. In examples, the predefined quantity is equal to one and corresponds to a single consumable item that is consumed during a single cycle. In other examples, the predefined quantity greater than one (e.g. two or three) and corresponds to more than one consumable item that is consumed during a single cycle. An operator can set a default value for the predefined quantity prior to operation of the device 22. An operator can set the predefined quantity by adjusting the default value, which can occur prior to, during or after the cycle. The method 80 can include setting the default value to the adjusted value.

At step 80F, a present value of the cycle counter is compared to a predetermined inventory or cycle threshold. Steps 80B-80E are repeated in response to the value being less than the predetermined cycle threshold. At step 80G, an alert or notification is generated in response to the inventory of the consumable item being equal to or less than the predetermined inventory or cycle threshold. In examples, step 80G includes causing a reorder request to be communicated to the third party vendor such that a quantity of the consumable item will be automatically ordered and delivered to a location of the device 22. The cycle counter can be reinitialized in response to receiving a resupply confirmation or manually by a user, for example.

In examples, step 80H includes generating an alert or notification in response to determining the non-occurrence of moving the door assembly 22D between the open and closed positions based on one or more predetermined criterion being met or not being met at step 80D. The alerts generated in response to the occurrence and non-occurrence of moving the door assembly 22D can be the same or can differ. For example, step 80D can include determining that thresholds T3 and/or T4 have not been met subsequent to thresholds T1 and/or T2 being met during the cycle of the device 22. A duration since thresholds T1 and/or T2 being met can be compared to a predefined duration or set of durations (e.g., 30 minutes and 60 minutes). Step 80H can include generating an alert in response to the non-occurrence of thresholds T3 and/or T4 for a duration that exceeds the predefined duration or set of durations.

Generation of alert(s) at step 80H can reduce a likelihood of clothing or other articles being stored in the device 22 for a relatively long duration. For example, an operator may cause the device 22 to execute a wash cycle, but may not remove the clothing from the device 22 prior to the clothing being musky. Step 80D is operable to determine or infer whether or not the operator actually removed the clothing from the device 22, such as during a transfer of the clothing between the device 22 and another device or unit (e.g., dryer). After detecting that a wash cycle is complete at step 80F and delivering a notification to the operator, the sensor(s) 26 can continue to monitor the device 22 to determine that the door assembly 22D has been moved between the open and closed positions and can determine or otherwise infer that the clothing has been removed from the device 22. Generation of alert(s) at steps 80G and/or 80H can prompt the operator to transfer or otherwise remove the clothing from the device 22. If after a predetermined duration (e.g., 30 minutes) the thresholds T3 and/or T4 have not been met, further alerts can be generated at step 80H to warn the operator that the operator has not removed the clothing from the device 22, and can to generate alerts periodically until the thresholds T3 and/or T4 have been met (e.g., every 30 or 60 minutes), indicating that the clothing has not been removed. In examples, step 80H includes sending an elevated alert or warning in response to determining that a relatively greater predetermined duration has elapsed (e.g., 8-12 hours), which may related to the clothing being in the device 22 for a relatively long duration that may be associated with an unpleasant odor. The operator can be provided with an option to discontinue future alerts and/or snooze alerts by manual or default selection through interaction with the system.

Although the different examples have the specific components shown in the illustrations, embodiments of this disclosure are not limited to those particular combinations. It is possible to use some of the components or features from one of the examples in combination with features or components from another one of the examples.

Although particular step sequences are shown, described, and claimed, it should be understood that steps may be performed in any order, separated or combined unless otherwise indicated and will still benefit from the present disclosure.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be understood that within the scope of the appended claims, the disclosure may be practiced other than as specifically described. For that reason the appended claims should be studied to determine true scope and content.

What is claimed is:

1. A system for monitoring a device comprising:
at least one sensor adjacent a device; and
a controller coupled to the at least one sensor, the controller comprising:
a comparison module operable to determine that at least one predetermined criterion is met in response to comparing one or more values sensed by the least one sensor, the at least one predetermined criterion based on a total number of cycles associated with operation of the device.

2. The system as recited in claim 1, wherein the comparison module is operable to generate an alert in response to determining that a predetermined cycle threshold is met, and the predetermined cycle threshold is based on a quantity of a consumable item associated with the device.

3. The system as recited in claim 2, wherein the device is associated with one or more operating profiles, and the comparison module is operable to determine that the at least one predetermined criterion is met in response to comparing one or more values sensed by the least one sensor to the one or more operating profiles, and the at least one predetermined criterion includes one or more predetermined operating thresholds associated with the one or more operating profiles.

4. The system as recited in claim 3, wherein the device is a washing machine, a clothes dryer or a coffee maker.

5. The system as recited in claim 4, wherein the at least one sensor is an accelerometer or a gyroscope fixedly attached to an external surface of the device.

6. The system as recited in claim 1, wherein the comparison module is operable to generate an alert in response to determining an occurrence of a maintenance event associated with at least one predetermined maintenance threshold.

7. The system as recited in claim 1, wherein the comparison module is operable to determine movement of a door assembly of the device between open and closed positions in response to the at least one predetermined criterion being met.

8. The system as recited in claim 7, wherein the device is a washing machine, and the comparison module is operable to generate an alert in response to determining a non-occurrence of moving the door assembly between the open and closed positions subsequent to completion of a wash cycle.

9. The system as recited in claim 1, wherein the comparison module is operable to generate an alert in response to determining a failure to initiate a cycle associated with operation of the device.

10. The system as recited in claim 1, wherein the at least one sensor is an accelerometer.

11. The system as recited in claim 1, wherein the at least one sensor is a gyroscope.

12. A system for monitoring a device comprising:
an appliance associated with a consumable item and one or more operating profiles;
at least one sensor secured to the appliance, the at least one sensor operable to sense one or more conditions of the appliance in operation;
a controller comprising:
a processor and a memory; and
an interface module coupled to the at least one sensor;
a comparison module operable to determine that at least one predetermined criterion is met in response to comparing one or more values of the one or more conditions sensed by the least one sensor to the one or more operating profiles, the at least one predetermined criterion based on a total number of cycles associated with operation of the device.

13. The system as recited in claim 12, wherein the device is a washing machine or a clothes dryer, and the one or more operating profiles include expected values of the one or more conditions.

14. The system as recited in claim 13, wherein the comparison module is operable to generate an alert in response to determining that the total number of cycles exceeds a predetermined cycle threshold, and the predetermined cycle threshold is associated with a quantity of the consumable item.

15. The system as recited in claim 14, wherein the alert corresponds to a reorder request of the consumable item.

16. The system as recited in claim 15, wherein the comparison module is operable to reset a cycle counter associated with the total number of cycles in response to a delivery notification communicated to the controller, and the delivery notification corresponds to fulfillment of the reorder request.

17. The system as recited in claim 14, wherein the one or more operating profiles relate to vibration of the appliance in operation, and the at least one sensor is an accelerometer or a gyroscope operable to sense vibration of the appliance in operation.

18. The system as recited in claim 14, wherein the at least one sensor is fixedly attached to an external surface of the device, and the controller and the sensor are at least partially received in a common housing.

19. A method of monitoring a device comprising:
establishing one or more operating profiles for an appliance;
sensing one or more conditions of the appliance;
determining a total number of cycles associated with the appliance in response to comparing the sensed conditions to the one or more operating profiles;
setting a cycle counter based on the total number of cycles; and
generating an alert in response to determining that a present value of the cycle counter is equal to or less than a predetermined cycle threshold.

20. The method as recited in claim 19, wherein the one or more conditions include vibration of the appliance.

21. The method as recited in claim 20, wherein the sensing step includes sensing vibration of the appliance with an accelerometer or a gyroscope secured to the appliance.

22. The method as recited in claim 19, wherein the appliance is associated with a consumable item, and further comprising:
setting the predetermined cycle threshold based on a quantity of the consumable item prior to the determining step; and
wherein the alert is a reorder request relating to the quantity of the consumable item.
